(19) United States
(12) Patent Application Publication
(10) Pub. No.: US 2024/0379389 A1
(43) Pub. Date: Nov. 14, 2024

(54) EXPANDING DEVICE, SEMICONDUCTOR CHIP MANUFACTURING METHOD, AND SEMICONDUCTOR CHIP

(71) Applicant: YAMAHA HATSUDOKI KABUSHIKI KAISHA, Iwata-shi, Shizuoka (JP)

(72) Inventor: Yoshikuni SUZUKI, Iwata-shi, Shizuoka (JP)

(73) Assignee: YAMAHA HATSUDOKI KABUSHIKI KAISHA, Iwata-shi, Shizuoka (JP)

(21) Appl. No.: 18/691,566

(22) PCT Filed: Apr. 27, 2022
(86) PCT No.: PCT/JP2022/019105

§ 371 Date: Mar. 13, 2024

(51) Int. Cl. H01L 21/67; H01L 21/66; H01L 21/683; H01L 21/78

(52) U.S. Cl. CPC H01L 21/67092; H01L 21/67103; H01L 21/78; H01L 22/12; H01L 21/6836

(57) ABSTRACT

An expanding device includes a cool air supplier and a cooling unit configured to cool an extensible sheet member on which a wafer including a plurality of semiconductor chips is arranged and a film provided on the wafer to a cooling temperature at which the film becomes harder than the sheet member. The expanding device further includes an expander configured to expand the sheet member cooled to the cooling temperature by the cool air supplier and the cooling unit to divide the wafer into the plurality of semiconductor chips.

### CROSS-REFERENCE TO RELATED APPLICATION

This application is a National Stage of International Patent Application No. PCT/JP2022/019105, filed Apr. 27, 2022, the entire content of which is incorporated herein by reference.

### BACKGROUND

### Technical Field

The present disclosure relates to an expanding device, a semiconductor chip manufacturing method, and a semiconductor chip.

### Background Art

Conventionally, an expanding device is known that cools and expands an extensible sheet member on which a wafer including a plurality of semiconductor chips is arranged. Such an expanding device is disclosed in Japanese Patent Laid-Open No. 2021-082648, for example.

Japanese Patent Laid-Open No. 2021-082648 discloses an expanding device that cools an extensible sheet member on which a wafer including a plurality of semiconductor chips is arranged to a predetermined cooling temperature, and expands the cooled sheet member to divide the wafer. Furthermore, the wafer is adhered to the sheet member via an adhesive layer, and the adhesive layer is divided together with the wafer by expanding the sheet member such that the wafer is divided into the plurality of semiconductor chips.

### SUMMARY

In the expanding device disclosed in Japanese Patent Laid-Open No. 2021-082648, when the sheet member is cooled to a predetermined cooling temperature and expanded, the adhesive layer does not harden when the cooling temperature is high, and thus it is difficult to reliably divide the adhesive layer. On the other hand, when the cooling temperature is low, the sheet member becomes too hard, and it is difficult to expand the sheet member. Therefore, there is a demand for an expanding device capable of reliably expanding an extensible sheet member on which a wafer including a plurality of semiconductor chips is arranged and capable of reliably dividing a film such as an adhesive layer provided on the wafer.

The present disclosure provides an expanding device capable of reliably expanding an extensible sheet member on which a wafer including a plurality of semiconductor chips is arranged and capable of reliably dividing a film provided on the wafer, a semiconductor chip manufacturing method that enables an extensible sheet member on which a wafer including a plurality of semiconductor chips is arranged to be reliably expanded and enables a film provided on the wafer to be reliably divided, and a semiconductor chip manufactured by the expanding device.

An expanding device according to a first aspect of the present disclosure includes a cooler configured to cool an extensible sheet member on which a wafer including a plurality of semiconductor chips is arranged and a film provided on the wafer to a cooling temperature at which the film becomes harder than the sheet member, and an expander configured to expand the sheet member cooled to the cooling temperature by the cooler to divide the wafer into the plurality of semiconductor chips.

In the expanding device according to the first aspect of the present disclosure, as described above, the cooler cools the sheet member and the film to the cooling temperature at which the film provided on the wafer becomes harder than the sheet member. Accordingly, the film can be divided together with the wafer, and the breakage of the sheet member can be reduced or prevented. Consequently, the extensible sheet member on which the wafer including the plurality of semiconductor chips is arranged can be reliably expanded, and the film provided on the wafer can be reliably divided. Thus, the yield of dividing the wafer by expansion can be further improved.

In the expanding device according to the first aspect, a magnitude relationship between a hardness of the sheet member and a hardness of the film with respect to temperature is preferably reversed at a predetermined temperature, and the cooler is preferably configured to cool the sheet member and the film to a temperature lower than the predetermined temperature at which the film becomes harder than the sheet member. Accordingly, expansion can be performed in a state in which the hardness of the sheet member and the hardness of the film are reversed and the film is harder than the sheet member, and thus the film can be more reliably divided.

In the expanding device according to the first aspect, the cooler is preferably configured to cool the sheet member and the film to the cooling temperature in a cooling temperature range in which the film is harder than the sheet member and a hardness of the sheet member is smaller than a predetermined value. Accordingly, the sheet member can be expanded in a state in which the sheet member and the film are cooled to the cooling temperature at which the sheet member does not become too hard and the film becomes hard.

In this case, the cooler is preferably configured to cool the sheet member and the film to a temperature on a higher side in the cooling temperature range when the sheet member has a larger variation in the hardness with respect to temperature than the film. Accordingly, even when the sheet member has a larger variation in the hardness with respect to temperature, the sheet member and the film can be cooled to a cooling temperature at which the sheet member does not break.

In the configuration in which the cooler cools the sheet member and the film to the cooling temperature determined in the cooling temperature range in which the film is harder than the sheet member and the hardness of the sheet member is smaller than the predetermined value, the cooler is preferably configured to cool the sheet member and the film to a temperature on a lower side in the cooling temperature range when the sheet member has a smaller variation in the hardness with respect to temperature than the film. Accordingly, even when the film has a larger variation in the hardness with respect to temperature, the film and the sheet member can be cooled to a cooling temperature at which the film can be reliably divided.

A semiconductor chip manufacturing method according to a second aspect of the present disclosure includes cooling an extensible sheet member on which a wafer including a plurality of semiconductor chips is arranged and a film provided on the wafer to a cooling temperature at which the film becomes harder than the sheet member, and expanding the sheet member cooled to the cooling temperature to divide the wafer into the plurality of semiconductor chips.

In the semiconductor chip manufacturing method according to the second aspect of the present disclosure, as described above, the sheet member and the film are cooled to the cooling temperature at which the film provided on the wafer becomes harder than the extensible sheet member on which the wafer including the plurality of semiconductor chips is arranged. Accordingly, the film can be divided together with the wafer, and the breakage of the sheet member can be reduced or prevented. Consequently, it is possible to provide the semiconductor chip manufacturing method that enables the extensible sheet member on which the wafer including the plurality of semiconductor chips is arranged to be reliably expanded, and enables the film provided on the wafer to be reliably divided. Thus, the yield of dividing the wafer by expansion can be further improved.

In the semiconductor chip manufacturing method according to the second aspect, a magnitude relationship between a hardness of the sheet member and a hardness of the film with respect to temperature is preferably reversed at a predetermined temperature, and the cooling the film preferably includes cooling the sheet member and the film to a temperature lower than the predetermined temperature at which the film becomes harder than the sheet member. Accordingly, expansion can be performed in a state in which the hardness of the sheet member and the hardness of the film are reversed and the film is harder than the sheet member, and thus the film can be more reliably divided.

The semiconductor chip manufacturing method according to the second aspect preferably further includes measuring a hardness of the sheet member and a hardness of the film with respect to temperature, and determining the cooling temperature based on measured results. Accordingly, the cooling temperature at which the film is divided and the sheet member does not break can be accurately determined based on the measured results of the hardness of the sheet member and the hardness of the film with respect to temperature.

In this case, the cooling the sheet member and the film to the cooling temperature preferably includes cooling the sheet member and the film to the cooling temperature determined in a cooling temperature range in which the film is harder than the sheet member and a hardness of the sheet member is smaller than a predetermined value. Accordingly, the sheet member can be expanded in a state in which the sheet member and the film are cooled to the cooling temperature at which the sheet member does not become too hard and the film becomes hard.

In the configuration in which the sheet material and the film are cooled to the cooling temperature determined in the cooling temperature range in which the film is harder than the sheet member and the hardness of the sheet member is smaller than the predetermined value, the cooling the sheet member and the film to the cooling temperature preferably includes cooling the sheet member and the film to the cooling temperature determined to be a temperature on a higher side in the cooling temperature range when the sheet member has a larger variation in the hardness with respect to temperature than the film. Accordingly, even when the sheet member has a larger variation in the hardness with respect to temperature, the sheet member and the film can be cooled to a cooling temperature at which the sheet member does not break.

In the configuration in which the sheet material and the film are cooled to the cooling temperature determined in the cooling temperature range in which the film is harder than the sheet member and the hardness of the sheet member is smaller than the predetermined value, the cooling the sheet member and the film to the cooling temperature preferably includes cooling the sheet member and the film to the cooling temperature includes cooling the sheet member and the film to the cooling temperature determined to be a temperature on a lower side in the cooling temperature range when the sheet member has a smaller variation in the hardness with respect to temperature than the film. Accordingly, even when the film has a larger variation in the hardness with respect to temperature, the film and the sheet member can be cooled to a cooling temperature at which the film can be reliably divided.

A semiconductor chip according to a third aspect of the present disclosure is manufactured by an expanding device including a cooler configured to cool an extensible sheet member on which a wafer including a plurality of semiconductor chips is arranged and a film provided on the wafer to a cooling temperature at which the film becomes harder than the sheet member, and an expander configured to expand the sheet member cooled to the cooling temperature by the cooler to divide the wafer into the plurality of semiconductor chips.

In the semiconductor chip according to the third aspect of the present disclosure, as described above, the sheet member and the film are cooled to the cooling temperature at which the film provided on the wafer becomes harder than the extensible sheet member on which the wafer including the plurality of semiconductor chips is arranged. Accordingly, the film can be divided together with the wafer, and the breakage of the sheet member can be reduced or prevented. Consequently, it is possible to provide the semiconductor chip manufactured by the expanding device capable of reliably expanding the extensible sheet member on which the wafer including the plurality of semiconductor chips is arranged and capable of reliably dividing the film provided on the wafer. Thus, the yield of dividing the wafer by expansion can be further improved.

According to the present disclosure, as described above, it is possible to reliably expand the extensible sheet member on which the wafer including the plurality of semiconductor chips is arranged, and reliably divide the film provided on the wafer.

### BRIEF DESCRIPTION OF THE DRAWINGS

FIG. 1 is a plan view showing a semiconductor wafer processing apparatus including a dicing device and an expanding device according to an embodiment;

FIG. 2 is a plan view showing a wafer ring structure to be processed in the semiconductor wafer processing apparatus according to the embodiment;

FIG. 3 is a sectional view taken along the line III-III in FIG. 2;

FIG. 4 is a plan view of the dicing device arranged adjacent to the expanding device according to the embodiment;

FIG. 5 is a side view showing the dicing device arranged adjacent to the expanding device according to the embodiment, as viewed from the Y2 direction side;

FIG. 6 is a plan view of the expanding device according to the embodiment;

FIG. 7 is a side view showing the expanding device according to the embodiment, as viewed from the Y2 direction side;

FIG. 8 is a side view showing the expanding device according to the embodiment, as viewed from the X1 direction side;

FIG. 9 is a block diagram showing the control configuration of the semiconductor wafer processing apparatus according to the embodiment;

FIG. 10 is a flowchart of the first half of a semiconductor chip manufacturing process of the semiconductor wafer processing apparatus according to the embodiment;

FIG. 11 is a flowchart of the second half of the semiconductor chip manufacturing process of the semiconductor wafer processing apparatus according to the embodiment;

FIG. 12 is a side view showing a state in which a clamp unit is arranged at a raised position in the expanding device according to the embodiment;

FIG. 13 is a side view showing a state in which the clamp unit is arranged at a lowered position in the expanding device according to the embodiment;

FIG. 14 is a side view showing a state in which an ultraviolet irradiator emits ultraviolet rays in the expanding device according to the embodiment;

FIG. 15 is a side sectional view showing a first example of the wafer ring structure according to the embodiment;

FIG. 16 is a side sectional view showing a second example of the wafer ring structure according to the embodiment;

FIG. 17 is a diagram showing a relationship between the cooling temperature and the hardness of each of a sheet member and a film of the wafer ring structure according to the embodiment;

FIG. 18 is a diagram showing a relationship between the cooling temperature and the hardness of each of the sheet member and the film of the wafer ring structure according to the embodiment when there are variations in the hardness of the sheet member; and

FIG. 19 is a diagram showing a relationship between the cooling temperature and the hardness of each of the sheet member and the film of the wafer ring structure according to the embodiment when there are variations in the hardness of the film.

### DETAILED DESCRIPTION

An embodiment embodying the present disclosure is hereinafter described on the basis of the drawings.

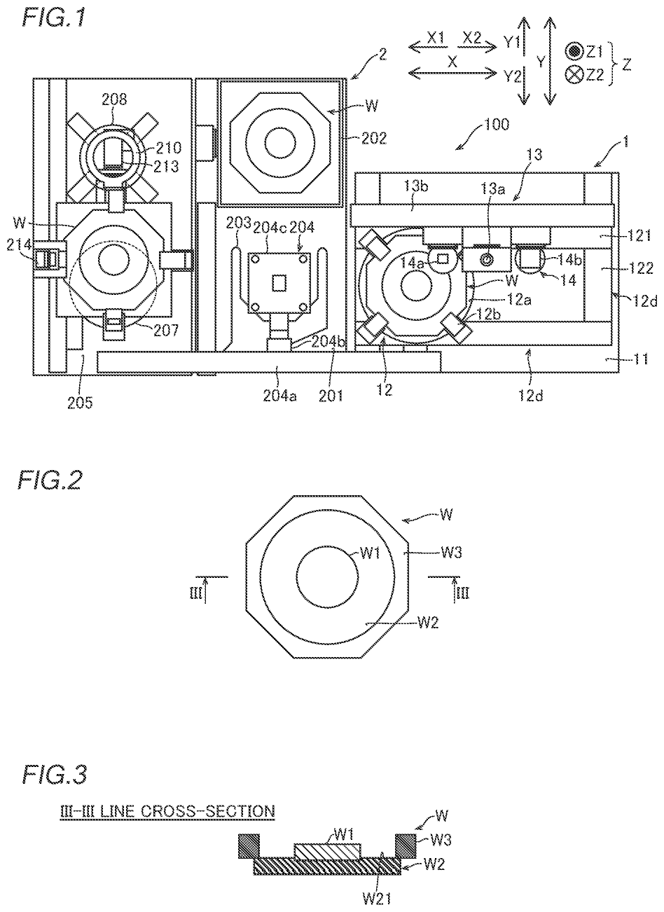

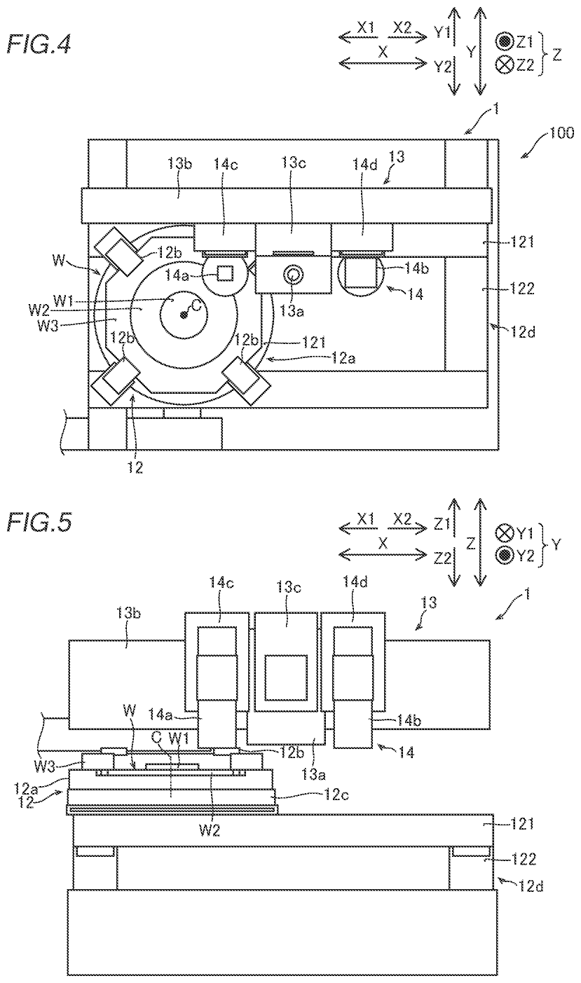

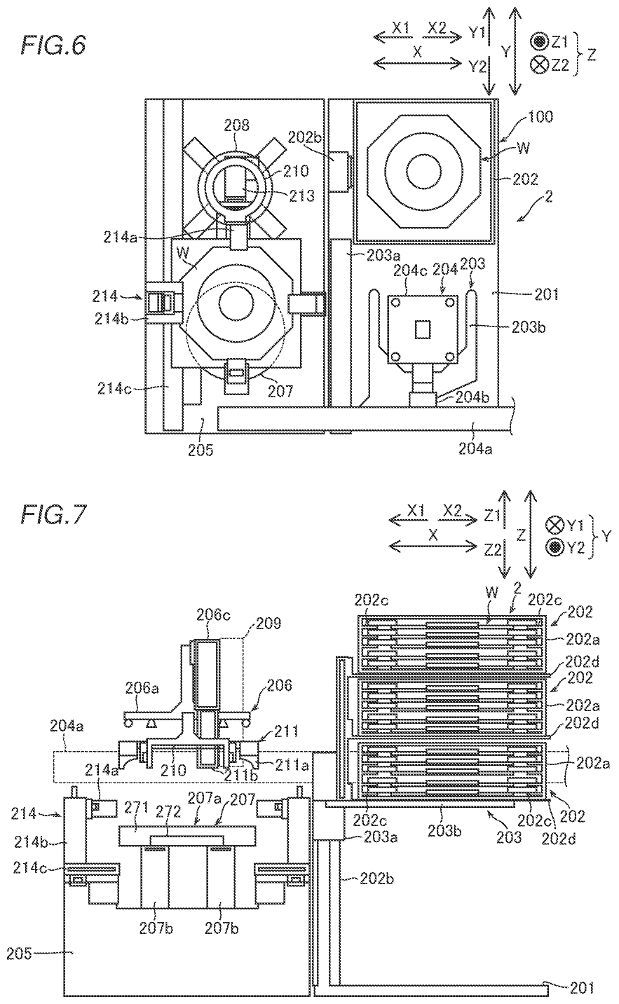

The configuration of a semiconductor wafer processing apparatus 100 according to the embodiment of the present disclosure is now described with reference to FIGS. 1 to 19.

### Semiconductor Wafer Processing Apparatus

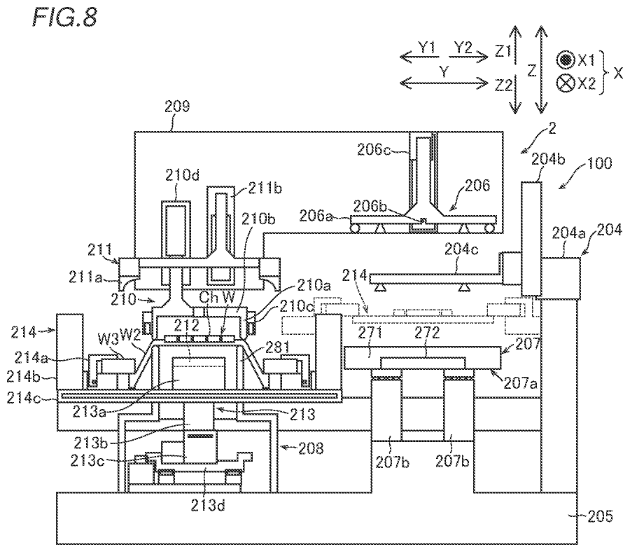

As shown in FIG. 1, the semiconductor wafer processing apparatus 100 is an apparatus that processes a wafer W1 provided on a wafer ring structure W. The semiconductor wafer processing apparatus 100 forms a modified layer in the wafer W1 and divides the wafer W1 along the modified layer to form a plurality of semiconductor chips Ch (see FIG. 8).

The wafer ring structure W is now described with reference to FIGS. 2 and 3. The wafer ring structure W includes the wafer W1, a sheet member W2, and a ring-shaped member W3.

The wafer W1 is a circular thin plate made of a crystal of a semiconductor material that is used as a material for a semiconductor integrated circuit. Inside the wafer W1, the modified layer is formed by modifying the inside along a dividing line by processing in the semiconductor wafer processing apparatus 100. That is, the wafer W1 is processed so as to be divisible along the dividing line. The sheet member W2 is an extensible adhesive tape. An adhesive layer is provided on the upper surface W21 of the sheet member W2. The wafer W1 is attached to the adhesive layer on the sheet member W2. The ring-shaped member W3 is a ring-shaped metal frame in a plan view. The ring-shaped member W3 is attached to the adhesive layer on the sheet member W2 while surrounding the wafer W1.

The semiconductor wafer processing apparatus 100 includes a dicing device 1 and an expanding device 2. Hereinafter, an upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 2 are aligned is defined as an X direction, a direction from the dicing device 1 toward the expanding device 2 in the X direction is defined as an X1 direction, and a direction from the expanding device 2 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

As shown in FIGS. 1, 4, and 5, the dicing device 1 emits a laser beam having a wavelength transmissive to the wafer W1 along the dividing line (street) to form the modified layer. The modified layer refers to a crack, a void, or the like formed inside the wafer W1 by the laser beam.

Specifically, the dicing device 1 includes a base 11, a chuck table unit 12, a laser 13, and an imager 14.

The base 11 is a base on which the chuck table unit 12 is installed. The base 11 has a rectangular shape in a plan view.

### Chuck Table Unit

The chuck table unit 12 includes a suction unit 12a, clamps 12b, a rotation mechanism 12c, and a table movement mechanism 12d. The suction unit 12a suctions the wafer ring structure W on the upper surface of the suction unit 12a on the Z1 direction side. The suction unit 12a is a table including a suction hole, a suction pipe line, etc. to suction the lower surface of the ring-shaped member W3 of the wafer ring structure W on the Z2 direction side. The suction unit 12a is supported by the table movement mechanism 12d via the rotation mechanism 12c. The clamps 12b are provided at an upper end of the suction unit 12a. The clamps 12b hold the wafer ring structure W suctioned by the suction unit 12a. The clamps 12b hold the ring-shaped member W3 of the wafer ring structure W suctioned by the suction unit 12a from the Z1 direction side. In this manner, the wafer ring structure W is held by the suction unit 12a and the clamps 12b.

The rotation mechanism 12c rotates the suction unit 12a in a circumferential direction around a rotation center axis C extending parallel to the Z direction. The rotation mechanism 12c is attached to an upper end of the table movement mechanism 12d. The table movement mechanism 12d moves the wafer ring structure W in the X and Y directions. The table movement mechanism 12d includes an X-direction movement mechanism 121 and a Y-direction movement mechanism 122. The X-direction movement mechanism 121 moves the rotation mechanism 12c in the X1 direction or the X2 direction. The X-direction movement mechanism 121 includes a linear conveyor module, or a ball screw and a drive including a motor with an encoder, for example. The Y-direction movement mechanism 122 moves the rotation mechanism 12c in the Y1 direction or the Y2 direction. The Y-direction movement mechanism 122 includes a linear conveyor module, or a ball screw and a drive including a motor with an encoder, for example.

### Laser

The laser 13 emits a laser beam to the wafer W1 of the wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c. The laser irradiator 13a emits a pulsed laser beam. The mounting member 13b is a frame to which the laser 13 and the imager 14 are mounted. The Z-direction movement mechanism 13c moves the laser 13 in the Z1 direction or the Z2 direction. The Z-direction movement mechanism 13c includes a linear conveyor module, or a ball screw and a drive including a motor with an encoder, for example. The laser irradiator 13a may be a laser irradiator that oscillates a continuous wave laser beam other than a pulsed laser beam as a laser beam as long as a modified layer can be formed by multiphoton absorption.

### Imager

The imager 14 images the wafer W1 of the wafer ring structure W held by the chuck table unit 12. The imager 14 is arranged on the Z1 direction side of the chuck table unit 12. The imager 14 includes a high-resolution camera 14a, a wide-angle camera 14b, a Z-direction movement mechanism 14c, and a Z-direction movement mechanism 14d.

The high-resolution camera 14a and the wide-angle camera 14b are near-infrared imaging cameras. The high-resolution camera 14a has a narrower viewing angle than the wide-angle camera 14b. The high-resolution camera 14a has a higher resolution than the wide-angle camera 14b. The wide-angle camera 14b has a wider viewing angle than the high-resolution camera 14a. The wide-angle camera 14b has a lower resolution than the high-resolution camera 14a. The high-resolution camera 14a is arranged on the X1 direction side of the laser irradiator 13a. The wide-angle camera 14b is arranged on the X2 direction side of the laser irradiator 13a. Thus, the high-resolution camera 14a, the laser irradiator 13a, and the wide-angle camera 14b are arranged adjacent to each other in this order from the X1 direction side toward the X2 direction side.

The Z-direction movement mechanism 14c moves the high-resolution camera 14a in the Z1 direction or Z2 direction. The Z-direction movement mechanism 14c includes a linear conveyor module, or a ball screw and a drive including a motor with an encoder, for example. The Z-direction movement mechanism 14d moves the wide-angle camera 14b in the Z1 direction or the Z2 direction. The Z-direction movement mechanism 14d includes a linear conveyor module, or a ball screw and a drive including a motor with an encoder, for example.

### Expanding Device

As shown in FIGS. 1, 6, and 7, the expanding device 2 divides the wafer W1 to form the plurality of semiconductor chips Ch (see FIG. 8). The expanding device 2 forms a sufficient gap between the plurality of semiconductor chips Ch. A modified layer is formed in the wafer W1 by emitting a laser beam having a wavelength transmissive to the wafer W1 along the dividing line (street) in the dicing device 1. In the expanding device 2, the plurality of semiconductor chips Ch are formed by dividing the wafer W1 along the modified layer formed in advance in the dicing device 1.

Therefore, in the expanding device 2, the wafer W1 is divided along the modified layer by expanding the sheet member W2. Furthermore, in the expanding device 2, the gap between the plurality of semiconductor chips Ch formed by division is widened by expanding the sheet member W2.

The expanding device 2 includes a base 201, a cassette unit 202, a lift-up hand unit 203, a suction hand unit 204, a base 205, a cool air supplier 206, a cooling unit 207, an expander 208, a base 209, an expansion maintaining member 210, a heat shrinker 211, an ultraviolet irradiator 212, a squeegee unit 213, and a clamp unit 214. The cool air supplier 206 and the cooling unit 207 are examples of a “cooler” in the claims.

### Base

The base 201 is a base on which the cassette unit 202 and the lift-up hand unit 203 are installed. The base 201 has a rectangular shape in a plan view.

### Cassette Unit

The cassette unit 202 can accommodate a plurality of wafer ring structures W. The cassette unit 202 includes wafer cassettes 202a, a Z-direction movement mechanism 202b, and pairs of placement portions 202c.

A plurality of (three) wafer cassettes 202a are arranged in the Z direction. Each of the wafer cassettes 202a has an accommodation space capable of accommodating a plurality of (five) wafer ring structures W. The wafer ring structure W is manually supplied and placed in the wafer cassette 202a. The wafer cassette 202a may accommodate one to four wafer ring structures W, or may accommodate six or more wafer ring structures W. Furthermore, one, two, or four or more wafer cassettes 202a may be arranged in the Z direction.

The Z-direction movement mechanism 202b moves the wafer cassettes 202a in the Z1 direction or the Z2 direction. The Z-direction movement mechanism 202b includes a linear conveyor module, or a ball screw and a drive including a motor with an encoder, for example. The Z-direction movement mechanism 202b also includes mounting tables 202d that supports the wafer cassettes 202a from below. A plurality of (three) mounting tables 202d are arranged according to the positions of the plurality of wafer cassettes 202a.

A plurality of (five) pairs of placement portions 202c are arranged inside the wafer cassette 202a. The ring-shaped member W3 of the wafer ring structure W is placed on the pair of placement portions 202c from the Z1 direction side. One of the pair of placement portions 202c protrudes in the X2 direction from the inner surface of the wafer cassette 202a on the X1 direction side. The other of the pair of placement portions 202c protrudes in the X1 direction from the inner surface of the wafer cassette 202a on the X2 direction side.

### Lift-up Hand Unit

The lift-up hand unit 203 can take out the wafer ring structure W from the cassette unit 202. Furthermore, the lift-up hand unit 203 can take the wafer ring structure W into the cassette unit 202.

Specifically, the lift-up hand unit 203 includes a Y-direction movement mechanism 203a and a lift-up hand 203b. The Y-direction movement mechanism 203a includes a linear conveyor module, or a ball screw and a drive including a motor with an encoder, for example. The lift-up hand 203b supports the ring-shaped member W3 of the wafer ring structure W from the Z2 direction side.

### Suction Hand Unit

The suction hand unit 204 suctions the ring-shaped member W3 of the wafer ring structure W from the Z1 direction side.

Specifically, the suction hand unit 204 includes an X-direction movement mechanism 204a, a Z-direction movement mechanism 204b, and a suction hand 204c. The X-direction movement mechanism 204a moves the suction hand 204c in the X direction. The Z-direction movement mechanism 204b moves the suction hand 204c in the Z direction. Each of the X-direction movement mechanism 204a and the Z-direction movement mechanism 204b includes a linear conveyor module, or a ball screw and a drive including a motor with an encoder, for example. The suction hand 204c suctions and supports the ring-shaped member W3 of the wafer ring structure W from the Z1 direction side. The suction hand 204c supports the ring-shaped member W3 of the wafer ring structure W by generating a negative pressure.

### Base

As shown in FIGS. 7 and 8, the base 205 is a base on which the expander 208, the cooling unit 207, the ultraviolet irradiator 212, and the squeegee unit 213 are installed. The base 205 has a rectangular shape in a plan view. In FIG. 8, the clamp unit 214 arranged on the Z1 direction side of the cooling unit 207 is indicated by dotted lines.

### Cool Air Supplier

The cool air supplier 206 supplies cool air to the sheet member W2 from the Z1 direction side when the sheet member W2 is expanded by the expander 208.

Specifically, the cool air supplier 206 includes a supplier main body 206a, a cool air supply port 206b, and a movement mechanism 206c. The cool air supply port 206b allows cool air supplied from a cool air supply device to flow out therethrough. The cool air supply port 206b is provided at an end of the supplier main body 206a on the Z2 direction side. The cool air supply port 206b is arranged in a central portion of the end of the supplier main body 206a on the Z2 direction side. The movement mechanism 206c includes a linear conveyor module, or a ball screw and a motor with an encoder, for example.

The cool air supply device is a device that generates cool air. The cool air supply device supplies air cooled by a heat pump, for example. Such a cool air supply device is installed on the base 205. The cool air supplier 206 and the cooling supply device are connected to each other by a hose (not shown).

### Cooling Unit

The cooling unit 207 cools the sheet member W2 from the Z2 direction side.

The cooling unit 207 includes a cooling member 207a including a cooling body 271 and a Peltier element 272, and a Z-direction movement mechanism 207b. The cooling body 271 is made of a member having a large heat capacity and a high thermal conductivity. The cooling body 271 is made of metal such as aluminum. The Peltier element 272 cools the cooling body 271. The cooling body 271 is not limited to aluminum, and may be another member having a large heat capacity and a high thermal conductivity. The Z-direction movement mechanism 207b is a cylinder.

The cooling unit 207 is movable in the Z1 direction or the Z2 direction by the Z-direction movement mechanism 207b. Thus, the cooling unit 207 is movable to a position contacting the sheet member W2 and a position spaced apart from the sheet member W2.

### Expander

The expander 208 expands the sheet member W2 of the wafer ring structure W to divide the wafer W1 along the dividing line.

The expander 208 includes an expanding ring 281. The expanding ring 281 expands the sheet member W2 by supporting the sheet member W2 from the Z2 direction side. The expanding ring 281 has a ring shape in a plan view. The structure of the expanding ring 281 is described below in detail.

### Base

The base 209 is a base material on which the cool air supplier 206, the expansion maintaining member 210, and the heat shrinker 211 are installed.

### Expansion Maintaining Member

As shown in FIGS. 7 and 8, the expansion maintaining member 210 presses the sheet member W2 from the Z1 direction side such that the sheet member W2 in the vicinity of the wafer W1 does not shrink due to heating by a heating ring 211a.

Specifically, the expansion maintaining member 210 includes a pressing ring 210a, a lid 210b, and an intake 210c. The pressing ring 210a has a ring shape in a plan view. The lid 210b is provided on the pressing ring 210a to close an opening of the pressing ring 210a. The intake 210c is an intake ring having a ring shape in a plan view. A plurality of intake ports are formed in the lower surface of the intake 210c on the Z2 direction side. The pressing ring 210a is moved in the Z direction by a Z-direction movement mechanism 210d. That is, the Z-direction movement mechanism 210d moves the pressing ring 210a to a position at which the sheet member W2 is pressed and a position away from the sheet member W2. The Z-direction movement mechanism 210d includes a linear conveyor module, or a ball screw and a drive including a motor with an encoder, for example.

### Heat Shrinker

The heat shrinker 211 shrinks the sheet member W2 expanded by the expander 208 by heating while maintaining the gap between the plurality of semiconductor chips Ch.

The heat shrinker 211 includes the heating ring 211a and a Z-direction movement mechanism 211b. The heating ring 211a has a ring shape in a plan view. The heating ring 211a includes a sheathed heater that heats the sheet member W2. The Z-direction movement mechanism 211b moves the heating ring 211a in the Z direction. The Z-direction movement mechanism 211b includes a linear conveyor module, or a ball screw and a drive including a motor with an encoder, for example.

### Ultraviolet Irradiator

The ultraviolet irradiator 212 emits ultraviolet rays Ut to the sheet member W2 in order to reduce the adhesive strength of the adhesive layer of the sheet member W2. Specifically, the ultraviolet irradiator 212 includes an ultraviolet illuminator. The ultraviolet irradiator 212 is arranged at an end of a press 213a of the squeegee unit 213, which is described below, on the Z1 direction side. The ultraviolet irradiator 212 emits the ultraviolet rays Ut to the sheet member W2 while moving together with the squeegee unit 213.

### Squeegee Unit

The squeegee unit 213 further divides the wafer W1 along the modified layer by locally pressing the wafer W1 from the Z2 direction side after the sheet member W2 is expanded. Specifically, the squeegee unit 213 includes the press 213a, a Z-direction movement mechanism 213b, an X-direction movement mechanism 213c, and a rotation mechanism 213d.

The press 213a generates a bending stress in the wafer W1 to divide the wafer W1 along the modified layer by being moved by the rotation mechanism 213d and the X-direction movement mechanism 213c while pressing the wafer W1 from the Z2 direction side via the sheet member W2. The press 213a presses the wafer W1 by being raised to a raised position on the Z1 direction side by the Z-direction movement mechanism 213b to contact the wafer W1 via the sheet member W2. When the press 213a is lowered to a lowered position on the Z2 direction side by the Z-direction movement mechanism 213b, the contact with the wafer W1 is released such that the wafer W1 is no longer pressed. The press 213a is a squeegee.

The press 213a is attached to an end of the Z-direction movement mechanism 213b on the Z1 direction side. The Z-direction movement mechanism 213b linearly moves the press 213a in the Z1 direction or the Z2 direction. The Z-direction movement mechanism 213b is a cylinder, for example. The Z-direction movement mechanism 213b is attached to an end of the X-direction movement mechanism 213c on the Z1 direction side.

The X-direction movement mechanism 213c is attached to an end of the rotation mechanism 213d on the Z1 direction side. The X-direction movement mechanism 213c linearly moves the press 213a in one direction. The X-direction movement mechanism 213c includes a linear conveyor module, or a ball screw and a drive including a motor with an encoder, for example.

In the squeegee unit 213, the press 213a is raised to the raised position by the Z-direction movement mechanism 213b. In the squeegee unit 213, the press 213a is moved in the Y direction by the X-direction movement mechanism 213c while locally pressing the wafer W1 from the Z2 direction side via the sheet member W2 such that the wafer W1 is divided. In the squeegee unit 213, the press 213a is lowered to the lowered position by the Z-direction movement mechanism 213b. In the squeegee unit 213, after the press 213a finishes moving in the Y direction, the press 213a is rotated 90 degrees by the rotation mechanism 213d.

In the squeegee unit 213, the press 213a is raised to the raised position by the Z-direction movement mechanism 213b. In the squeegee unit 213, after the press 213a is rotated 90 degrees, the press 213a is moved in the X direction by the X-direction movement mechanism 213c while locally pressing the wafer W1 from the Z2 direction side via the sheet member W2 such that the wafer W1 is divided.

### Clamp Unit

The clamp unit 214 holds the ring-shaped member W3 of the wafer ring structure W. Specifically, the clamp unit 214 includes a gripper 214a, a Z-direction movement mechanism 214b, and a Y-direction movement mechanism 214c. The gripper 214a supports the ring-shaped member W3 from the Z2 direction side and presses the ring-shaped member W3 from the Z1 direction side. Thus, the ring-shaped member W3 is held by the gripper 214a. The gripper 214a is attached to the Z-direction movement mechanism 214b.

The Z-direction movement mechanism 214b moves the clamp unit 214 in the Z direction. Specifically, the Z-direction movement mechanism 214b moves the gripper 214a in the Z1 direction or the Z2 direction. The Z-direction movement mechanism 214b includes a linear conveyor module, or a ball screw and a drive including a motor with an encoder, for example. The Z-direction movement mechanism 214b is attached to the Y-direction movement mechanism 214c. The Y-direction movement mechanism 214c moves the Z-direction movement mechanism 214b in the Y1 direction or the Y2 direction. The Y-direction movement mechanism 214c includes a linear conveyor module, or a ball screw and a drive including a motor with an encoder, for example.

### Control Configuration of Semiconductor Wafer Processing Apparatus

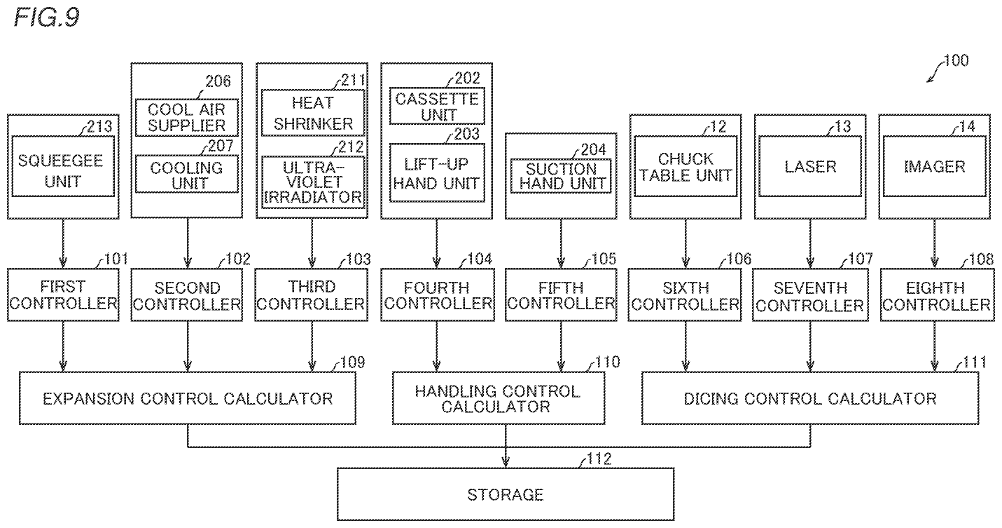

As shown in FIG. 9, the semiconductor wafer processing apparatus 100 includes a first controller 101, a second controller 102, a third controller 103, a fourth controller 104, a fifth controller 105, a sixth controller 106, a seventh controller 107, an eighth controller 108, an expansion control calculator 109, a handling control calculator 110, a dicing control calculator 111, and a storage 112.

The first controller 101 controls the squeegee unit 213. The first controller 101 includes a central processing unit (CPU) and a storage including a read-only memory (ROM) and a random access memory (RAM), for example. The first controller 101 may include, as a storage, a hard disk drive (HDD) that retains stored information even after the voltage is cut off, for example. The HDD may be provided in common for the first controller 101, the second controller 102, the third controller 103, the fourth controller 104, the fifth controller 105, the sixth controller 106, the seventh controller 107, and the eighth controller 108.

The second controller 102 controls the cool air supplier 206 and the cooling unit 207. The second controller 102 includes a CPU and a storage including a ROM and a RAM, for example. The third controller 103 controls the heat shrinker 211 and the ultraviolet irradiator 212. The third controller 103 includes a CPU and a storage including a ROM and a RAM, for example. The second controller 102 and the third controller 103 may include, as a storage, an HDD that retains stored information even after the voltage is cut off.

The fourth controller 104 controls the cassette unit 202 and the lift-up hand unit 203. The fourth controller 104 includes a CPU and a storage including a ROM and a RAM, for example. The fifth controller 105 controls the suction hand unit 204. The fifth controller 105 includes a CPU and a storage including a ROM and a RAM, for example. The fourth controller 104 and the fifth controller 105 may include, as a storage, an HDD that retains stored information even after the voltage is cut off, for example.

The sixth controller 106 controls the chuck table unit 12. The sixth controller 106 includes a CPU and a storage including a ROM and a RAM, for example. The seventh controller 107 controls the laser 13. The seventh controller 107 includes a CPU and a storage including a ROM and a RAM, for example. The eighth controller 108 controls the imager 14. The eighth controller 108 includes a CPU and a storage including a ROM and a RAM, for example. The sixth controller 106, the seventh controller 107, and the eighth controller 108 may include, as a storage, an HDD that retains stored information even after the voltage is cut off, for example.

The expansion control calculator 109 performs calculations regarding a process to expand the sheet member W2 based on the processing results of the first controller 101, the second controller 102, and the third controller 103. The expansion control calculator 109 includes a CPU and a storage including a ROM and a RAM, for example.

The handling control calculator 110 performs calculations regarding a process to move the wafer ring structure W based on the processing results of the fourth controller 104 and the fifth controller 105. The handling control calculator 110 includes a CPU and a storage including a ROM and a RAM, for example.

The dicing control calculator 111 performs calculations regarding a process to dice the wafer W1 based on the processing results of the sixth controller 106, the seventh controller 107, and the eighth controller 108. The dicing control calculator 111 includes a CPU and a storage including a ROM and a RAM, for example.

The storage 112 stores programs for operating the dicing device 1 and the expanding device 2. The storage 19 includes a ROM, a RAM, and an HDD, for example.

### Semiconductor Chip Manufacturing Process

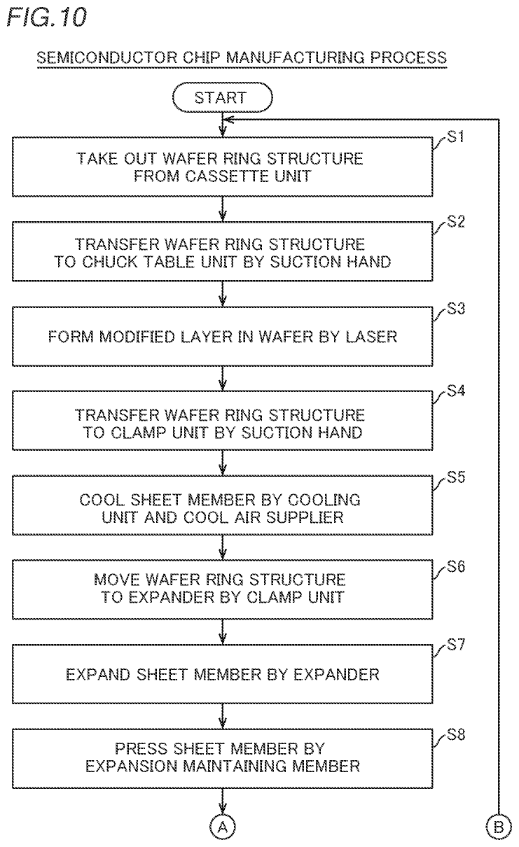

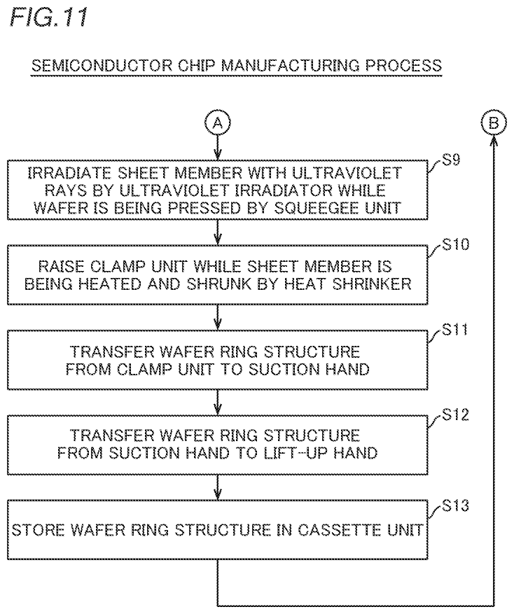

The overall operation of the semiconductor wafer processing apparatus 100 is described below with reference to FIGS. 10 and 11.

In step S1, the wafer ring structure W is taken out from the cassette unit 202. That is, after the wafer ring structure W stored in the cassette unit 202 is supported by the lift-up hand 203b, the lift-up hand 203b is moved in the Y1 direction by the Y-direction movement mechanism 31 such that the wafer ring structure W is taken out from the cassette unit 202. In step S2, the wafer ring structure W is transferred to the chuck table unit 12 of the dicing device 1 by the suction hand 204c. That is, the wafer ring structure W taken out from the cassette unit 202 is moved in the X2 direction by the X-direction movement mechanism 204a while being suctioned by the suction hand 204c. The wafer ring structure W that has been moved in the X2 direction is transferred from the suction hand 204c to the chuck table unit 12 and then held by the chuck table unit 12.

In step S3, a modified layer is formed in the wafer W1 by the laser 13. In step S4, the wafer ring structure W including the wafer W1 in which the modified layer has been formed is transferred to the clamp unit 214 by the suction hand 204c. In step S5, the sheet member W2 is cooled by the cool air supplier 206 and the cooling unit 207. That is, the wafer ring structure W held by the clamp unit 214 is moved (lowered) in the Z2 direction by the Z-direction movement mechanism 214b to contact the cooling unit 207, and the cool air supplier 206 supplies cool air from the Z1 direction side to cool the sheet member W2.

In step S6, the wafer ring structure W is moved to the expander 208 by the clamp unit 214. That is, the wafer ring structure W with the cooled sheet member W2 is moved in the Y1 direction by the Y-direction movement mechanism 214c while being held by the clamp unit 214. In step S7, the sheet member W2 is expanded by the expander 208. That is, the wafer ring structure W is moved in the Z2 direction by the Z-direction movement mechanism 214b while being held by the clamp unit 214. Then, the sheet member W2 contacts the expanding ring 281 and is expanded by being pulled by the expanding ring 281. Thus, the wafer W1 is divided along the dividing line (modified layer).

In step S8, the expanded sheet member W2 is pressed from the Z1 direction side by the expansion maintaining member 210. That is, the pressing ring 210a is moved (lowered) in the Z2 direction by the Z-direction movement mechanism 210d until it contacts the sheet member W2. Then, the process advances from a point A in FIG. 10 through a point A in FIG. 11 to step S9.

As shown in FIG. 11, in step S9, after the sheet member W2 is pressed by the expansion maintaining member 210, the sheet member W2 is irradiated with ultraviolet rays Ut by the ultraviolet irradiator 212 while the wafer W1 is being pressed by the squeegee unit 213. Thus, the wafer W1 is further divided by the squeegee unit 213. In addition, the adhesive strength of the sheet member W2 is reduced by the ultraviolet rays Ut emitted from the ultraviolet irradiator 212.

In step S10, while the sheet member W2 is being heated and shrunk by the heat shrinker 211, the clamp unit 214 is raised. At this time, the intake 210c takes in air in the vicinity of the heated sheet member W2. In step S11, the wafer ring structure W is transferred from the clamp unit 214 to the suction hand 204c. That is, the wafer ring structure W is moved in the Y2 direction by the Y-direction movement mechanism 214c while being held by the clamp unit 214. Then, the wafer ring structure W is suctioned by the suction hand 204c after the holding by the clamp unit 214 is released on the Z1 direction side of the cooling unit 207.

In step S12, the wafer ring structure W is transferred to the lift-up hand 203b by the suction hand 204c. In step S13, the wafer ring structure W is stored in the cassette unit 202. That is, the wafer ring structure W supported by the lift-up hand 203b is moved in the Y1 direction by the Y-direction movement mechanism 203a to be stored in the cassette unit 202. Thus, the process performed on one wafer ring structure W is terminated. Then, the process returns from a point B in FIG. 11 through a point B in FIG. 10 to step S1.

### Detailed Configuration of Expander, Expansion Maintaining Member, Ultraviolet Irradiator, and Squeegee Unit

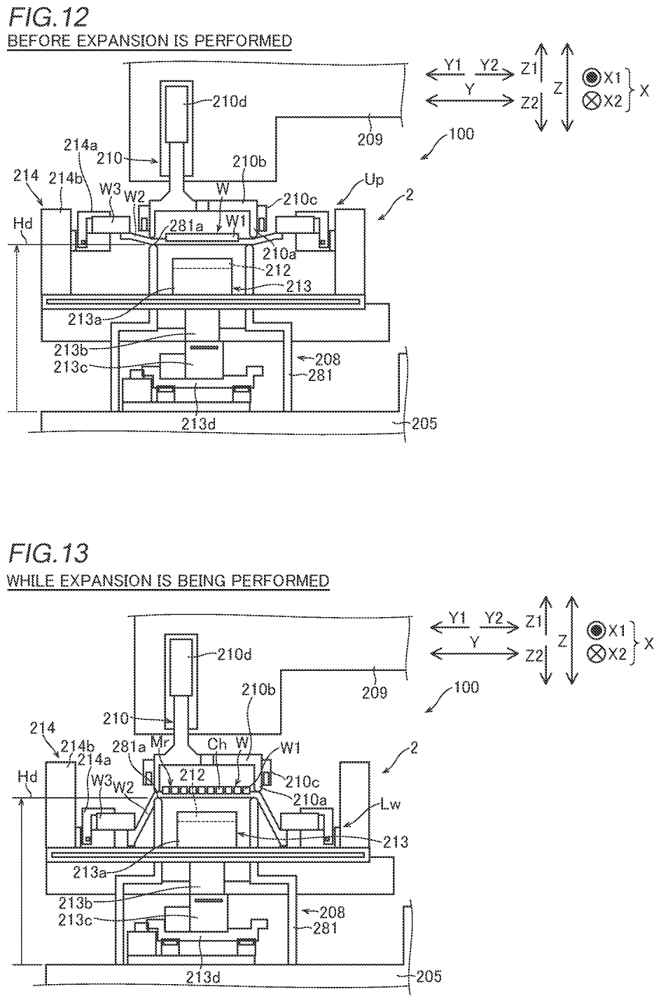

The detailed configuration of the expander 208, the expansion maintaining member 210, the ultraviolet irradiator 212, and the squeegee unit 213 is now described with reference to FIGS. 12 and 13. In FIG. 12, the heat shrinker 211 of the expanding device 2 is not illustrated for convenience.

FIG. 12 shows the state of the expanding device 2 before the sheet member W2 is expanded by the expanding ring 281. The clamp unit 214 is arranged at a raised position Up. That is, the gripper 214a is arranged at the raised position Up by the Z-direction movement mechanism 214b.

FIG. 13 shows the state of the expanding device 2 in which the sheet member W2 is being expanded by the expanding ring 281. The clamp unit 214 is arranged at a lowered position Lw. That is, the gripper 214a is moved in the Z2 direction from the raised position Up toward the lowered position Lw by the Z-direction movement mechanism 214b.

The sheet member W2 is expanded by contacting an upper end 281a of the expanding ring 281 when the gripper 214a is moved in the Z2 direction from the raised position Up toward the lowered position Lw. At this time, the wafer W1 is pulled by the sheet member W2 such that a tensile stress is generated in the wafer W1, and thus the wafer W1 is divided along the modified layer formed in the wafer W1. Thus, the plurality of semiconductor chips Ch are formed.

### Expander

The expander 208 includes the expanding ring 281 that expands the sheet member W2 while the clamp unit 214 holds the wafer ring structure W to divide the wafer W1 into the plurality of semiconductor chips Ch spaced apart from each other by an interval Mr. That is, the expanding ring 281 expands the sheet member W2 by the clamp unit 214 moved in the Z2 direction from the raised position Up toward the lowered position Lw by the Z-direction movement mechanism 214b.

The expanding ring 281 is fixed on the base 205. The upper end 281a of the expanding ring 281 is arranged at a predetermined height Hd in the Z direction. The predetermined height Hd is a height with the upper surface of the base 205 as a reference. In this manner, the upper end 281a of the expanding ring 281 is maintained at the predetermined height Hd.

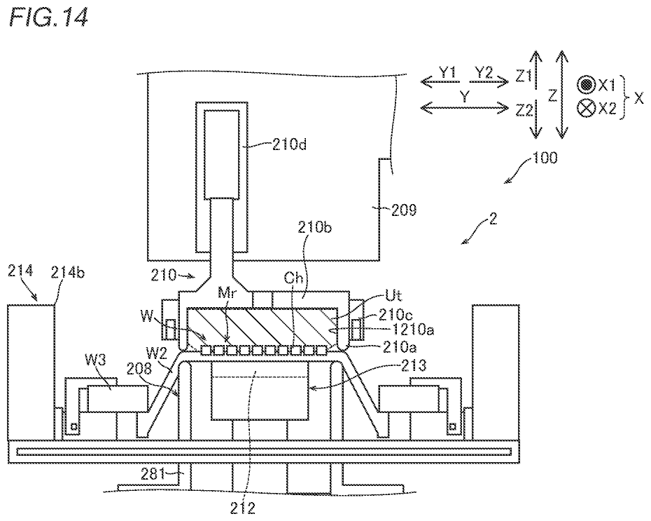

As shown in FIG. 14, the expansion maintaining member 210 maintains the expanded state of the sheet member W2 in the vicinity of the wafer W1. In FIG. 14, the heat shrinker 211 of the expanding device 2 is not illustrated for convenience.

Specifically, the expansion maintaining member 210 includes the pressing ring 210a and the lid 210b.

The pressing ring 210a has a cylindrical shape surrounding the wafer W1 in a plan view. The lid 210b covers the opening of the pressing ring 210a in the Z1 direction. The lid 210b is provided on the inner side 1210a of the pressing ring 210a to close the opening of the pressing ring 210a in the Z1 direction. The lid 210b is provided at an end of the inner side 1210a of the pressing ring 210a on the Z1 direction side. The inner side 1210a is the inner side of the cylindrical pressing ring 210a in the radial direction.

The ultraviolet irradiator 212 emits ultraviolet rays Ut to the expanded sheet member W2 from the Z2 direction side. Furthermore, the ultraviolet irradiator 212 is arranged on the Z2 direction side of the wafer W1 of the expanded sheet member W2.

The cylindrical pressing ring 210a and the lid 210b cover the wafer W1 from the Z1 direction side to prevent the ultraviolet rays Ut emitted from the ultraviolet irradiator 212 from leaking to the outside from the expansion maintaining member 210. Thus, the expansion maintaining member 210 has not only a function of maintaining the expanded state of the sheet member W2 in the vicinity of the wafer W1, but also a function of shielding the ultraviolet rays Ut. The extension maintaining member 210 is made of metal such as stainless steel in order to reduce or prevent a deterioration of the material caused by shielding the ultraviolet rays Ut.

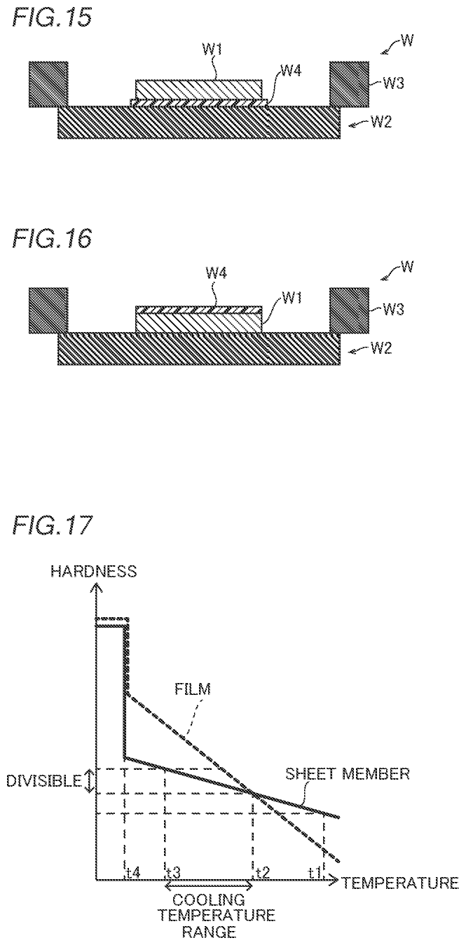

As shown in FIGS. 15 and 16, the wafer W1 includes a film W4. In an example shown in FIG. 15, the film W4 is provided between the wafer W1 and the sheet member W2. In an example shown in FIG. 16, the film W4 is provided on the side opposite to the sheet member W2 with respect to the wafer W1. The film W4 is an adhesive layer such as a die attach film (DAF) or an insulating film such as a Low-k film, for example.

As shown in FIG. 17, the sheet member W2 and the film W4 are hardened by cooling. When the sheet member W2 does not harden as in a case of cooling to a temperature t1, only the sheet member W2 on the outer side of the wafer W1 extends when expansion is performed, and the wafer W1 is not divided. On the other hand, when the sheet member W2 is too hard as in a case of cooling to a temperature t3, the sheet member W2 breaks when expansion is performed. When the film W4 does not harden as in a case of cooling to the temperature t1, the film W4 extends and is not divided together with the wafer W1 when expansion is performed. When the sheet member W2 and the film W4 are extremely cooled as in a case of cooling to a temperature t4, the sheet member W2 and the film W4 are solidified. Therefore, when expansion is performed, it is necessary to cool the sheet member W2 and the film W4 to an appropriate cooling temperature.

In this embodiment, the cool air supplier 206 and the cooling unit 207 cool the sheet member W2 and the film W4 to a cooling temperature at which the film W4 provided on the wafer W1 becomes harder than the sheet member W2. Specifically, the cool air supplier 206 and the cooling unit 207 cool the sheet member W2 and the film W4 to a cooling temperature in a range lower than a temperature t2 at which the sheet member W2 becomes less hard than the film W4 and higher than the temperature t3 at which the sheet member W2 does not become too hard.

That is, a semiconductor chip manufacturing method by this expanding device 2 includes a step of cooling the sheet member W2 and the film W4 to the cooling temperature at which the film W4 provided on the wafer W1 becomes harder than the extensible sheet member W2 on which the wafer W1 including the plurality of semiconductor chips Ch is arranged, and a step of expanding the sheet member W2 cooled to the cooling temperature to divide the wafer W1 into the plurality of semiconductor chips Ch.

The semiconductor chip Ch manufactured by this expanding device 2 is manufactured by the expanding device 2 including the cool air supplier 206 and the cooling unit 207 that cool the sheet member W2 and the film W4 to the cooling temperature at which the film W4 provided on the wafer W1 becomes harder than the extensible sheet member W2 on which the wafer W1 including the plurality of semiconductor chips Ch is arranged, and the expander 208 that expands the sheet member W2 cooled to the cooling temperature by the cool air supplier 206 and the cooling unit 207 to divide the wafer W1 into the plurality of semiconductor chips Ch.

In this embodiment, the magnitude relationship between the hardness of the sheet member W2 and the hardness of the film W4 with respect to temperature is reversed at a predetermined temperature, and the cool air supplier 206 and the cooling unit 207 cool the sheet member W2 and the film W4 to a temperature lower than the predetermined temperature at which the film W4 becomes harder than the sheet member W2. In an example shown in FIG. 17, the magnitude relationship between the hardness of the sheet member W2 and the hardness of the film W4 with respect to temperature is reversed at the temperature t2.

The cool air supplier 206 and the cooling unit 207 cool the sheet member W2 and the film W4 to a cooling temperature in a cooling temperature range in which the film W4 is harder than the sheet member W2 and the hardness of the sheet member W2 is smaller than a predetermined value. In the example shown in FIG. 17, the cool air supplier 206 and the cooling unit 207 cool the sheet member W2 and the film W4 to a cooling temperature in a cooling temperature range higher than the temperature t3 and lower than the temperature t2.

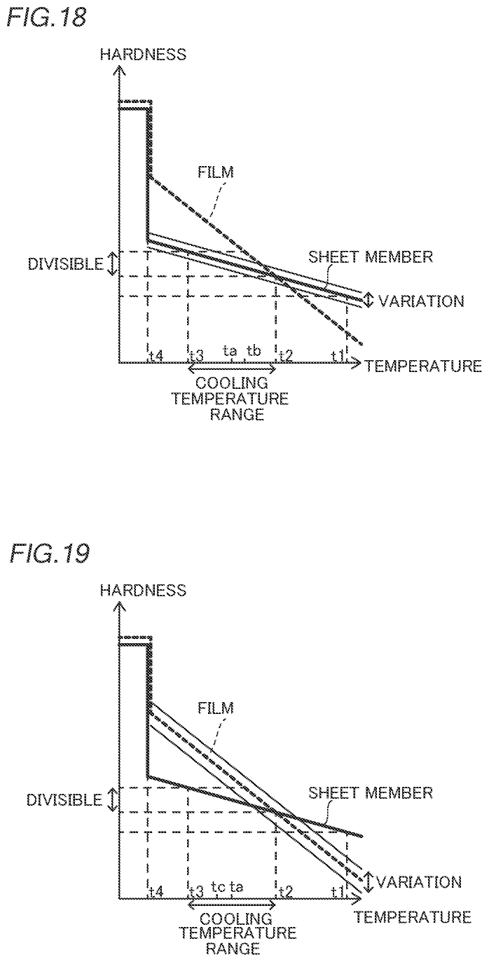

As shown in FIG. 18, when the sheet member W2 has larger variations in the hardness with respect to temperature than the film W4, the cool air supplier 206 and the cooling unit 207 cool the sheet member W2 and the film W4 to a temperature on the higher side in the cooling temperature range. In an example shown in FIG. 18, the cool air supplier 206 and the cooling unit 207 cool the sheet member W2 and the film W4 to a temperature tb higher than a central temperature ta in the cooling temperature range (the temperature range higher than the temperature t2 and lower than the temperature t3) when the sheet member W2 has large variations in the hardness with respect to temperature. That is, when the hardness of the sheet member W2 with respect to temperature varies, the cooling temperature is set to the temperature tb higher than the central temperature ta in the cooling temperature range such that the sheet member W2 does not become too hard.

As shown in FIG. 19, when the sheet member W2 has smaller variations in the hardness with respect to temperature than the film W4, the cool air supplier 206 and the cooling unit 207 cool the sheet member W2 and the film W4 to a temperature on the lower side in the cooling temperature range. In an example shown in FIG. 19, the cool air supplier 206 and the cooling unit 207 cool the sheet member W2 and the film W4 to a temperature tc lower than the central temperature ta in the cooling temperature range (the temperature range higher than the temperature t2 and lower than the temperature t3) when the film W4 has large variations in the hardness with respect to temperature. That is, when the hardness of the film W4 with respect to temperature varies, the cooling temperature is set to the temperature tc lower than the central temperature ta in the cooling temperature range in order to reliably harden the film W4.

The cooling temperature at which the cool air supplier 206 and the cooling unit 207 provide cooling is set (determined) in advance by an operator. Specifically, the hardness of the sheet member W2 and the hardness of the film W4 with respect to temperature are measured, and the cooling temperature is determined based on the measured results.

### Advantageous Effects of Embodiment

According to this embodiment, the following advantageous effects are achieved.

According to this embodiment, as described above, the cool air supplier 206 and the cooling unit 207 cool the sheet member W2 and the film W4 to the cooling temperature at which the film W4 provided on the wafer W1 becomes harder than the sheet member W2. Accordingly, the film W4 can be divided together with the wafer W1, and the breakage of the sheet member W2 can be reduced or prevented. Consequently, the extensible sheet member W2 on which the wafer W1 including the plurality of semiconductor chips Ch is arranged can be reliably expanded, and the film W4 provided on the wafer W1 can be reliably divided. Thus, the yield of dividing the wafer by expansion can be further improved.

According to this embodiment, as described above, the magnitude relationship between the hardness of the sheet member W2 and the hardness of the film W4 with respect to temperature is reversed at the predetermined temperature, and the cool air supplier 206 and the cooling unit 207 cool the sheet member W2 and the film W4 to the temperature lower than the predetermined temperature at which the film W4 becomes harder than the sheet member W2. Accordingly, expansion can be performed in a state in which the hardness of the sheet member W2 and the hardness of the film W4 are reversed and the film W4 is harder than the sheet member W2, and thus the film W4 can be more reliably divided.

According to this embodiment, as described above, the cool air supplier 206 and the cooling unit 207 cool the sheet member W2 and the film W4 to the cooling temperature in the cooling temperature range in which the film W4 is harder than the sheet member W2 and the hardness of the sheet member W2 is smaller than the predetermined value. Accordingly, the sheet member W2 can be expanded in a state in which the sheet member W2 and the film W4 are cooled to the cooling temperature at which the sheet member W2 does not become too hard and the film W4 becomes hard.

According to this embodiment, as described above, the cool air supplier 206 and the cooling unit 207 cool the sheet member W2 and the film W4 to the temperature on the higher side in the cooling temperature range when the sheet member W2 has larger variations in the hardness with respect to temperature than the film W4. Accordingly, even when the sheet member W2 has larger variations in the hardness with respect to temperature, the sheet member W2 and the film W4 can be cooled to a cooling temperature at which the sheet member W2 does not break.

According to this embodiment, as described above, the cool air supplier 206 and the cooling unit 207 cool the sheet member W2 and the film W4 to the temperature on the lower side in the cooling temperature range when the sheet member W2 has smaller variations in the hardness with respect to temperature than the film W4. Accordingly, even when the film W4 has larger variations in the hardness with respect to temperature, the film W4 and the sheet member W2 can be cooled to a cooling temperature at which the film W4 can be reliably divided.

According to this embodiment, as described above, the hardness of the sheet member W2 and the hardness of the film W4 with respect to temperature are measured, and the cooling temperature is determined based on the measured results. Accordingly, the cooling temperature at which the film W4 is divided and the sheet member W2 does not break can be accurately determined based on the measured results of the hardness of the sheet member W2 and the hardness of the film W4 with respect to temperature.

### Modified Examples

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the dicing device that dices the wafer is provided together with the expanding device has been shown in the aforementioned embodiment, the present disclosure is not restricted to this. In the present disclosure, the expanding device may be used alone without providing the dicing device together with the expanding device. Alternatively, in addition to the dicing device together with the expanding device, another device may be further provided. For example, a grinding device that grinds the wafer may be further provided together with the expanding device and the dicing device.

While the example in which the sheet member and the film are cooled by both the cool air from the cool air supplier as the cooler and the Peltier element of the cooling unit as the cooler has been shown in the aforementioned embodiment, the present disclosure is not restricted to this. In the present disclosure, the sheet member and the film may be cooled by either the cool air from the cool air supplier or the Peltier element.

While the example in which the position at which the cooler cools the sheet member and the film is different from the position at which the expander expands the sheet member has been shown in the aforementioned embodiment, the present disclosure is not restricted to this. In the present disclosure, the position at which the cooler cools the sheet member and the film may be the same as the position at which the expander expands the sheet member.

While the example in which the dicing device performs dicing by irradiating the wafer with a laser beam to generate cracks has been shown in the aforementioned embodiment, the present disclosure is not restricted to this. In the present disclosure, the dicing device may cut the wafer by laser irradiation, or may cut the wafer with a blade.

While the example in which the expansion maintaining member includes the lid has been shown in the aforementioned embodiment, the present disclosure is not restricted to this. In the present disclosure, the expansion maintaining member may not include the lid.

While the example in which the expanding device includes the ultraviolet irradiator has been shown in the aforementioned embodiment, the present disclosure is not restricted to this. In the present disclosure, the expanding device may not include the ultraviolet irradiator.

While the example in which the expanding device includes the squeegee unit has been shown in the aforementioned embodiment, the present disclosure is not restricted to this. In the present disclosure, the expanding device may not include the squeegee unit.

While the example in which the squeegee unit of the expanding device is arranged inside the expanding ring has been shown in the aforementioned embodiment, the present disclosure is not restricted to this. In the present disclosure, the squeegee unit of the expanding device may be arranged outside the expanding ring. In this case, the squeegee unit may be provided between the expander and the cooler.

While the control process is described, using the flowchart described in a manner driven by a flow in which processes are performed in order along a process flow for the convenience of illustration in the aforementioned embodiment, the present disclosure is not restricted to this. In the present disclosure, the control process may be performed in an event-driven manner in which processes are performed on an event basis. In this case, the control process may be performed in a complete event-driven manner or in a combination of an event-driven manner and a manner driven by a flow.

What is claimed is:

1. An expanding device comprising:
a cooler configured to cool an extensible sheet member on which a wafer including a plurality of semiconductor chips is arranged and a film on the wafer to a cooling temperature at which the film becomes harder than the sheet member; and
an expander configured to expand the sheet member cooled to the cooling temperature by the cooler to divide the wafer into the plurality of semiconductor chips.

2. The expanding device according to claim 1, wherein
a magnitude relationship between a hardness of the sheet member and a hardness of the film with respect to temperature is reversed at a predetermined temperature; and
the cooler is configured to cool the sheet member and the film to a temperature lower than the predetermined temperature at which the film becomes harder than the sheet member.

3. The expanding device according to claim 1, wherein
the cooler is configured to cool the sheet member and the film to the cooling temperature in a cooling temperature range in which the film is harder than the sheet member and a hardness of the sheet member is smaller than a predetermined value.

4. The expanding device according to claim 3, wherein
the cooler is configured to cool the sheet member and the film to a temperature on a higher side in the cooling temperature range when the sheet member has a larger variation in the hardness with respect to temperature than the film.

5. The expanding device according to claim 3, wherein
the cooler is configured to cool the sheet member and the film to a temperature on a lower side in the cooling temperature range when the sheet member has a smaller variation in the hardness with respect to temperature than the film.

6. A semiconductor chip manufacturing method comprising:
cooling an extensible sheet member on which a wafer including a plurality of semiconductor chips is arranged and a film on the wafer to a cooling temperature at which the film becomes harder than the sheet member; and
expanding the sheet member cooled to the cooling temperature to divide the wafer into the plurality of semiconductor chips.

7. The semiconductor chip manufacturing method according to claim 6, wherein
a magnitude relationship between a hardness of the sheet member and a hardness of the film with respect to temperature is reversed at a predetermined temperature; and
the cooling the film includes cooling the sheet member and the film to a temperature lower than the predetermined temperature at which the film becomes harder than the sheet member.

8. The semiconductor chip manufacturing method according to claim 6, further comprising:
measuring a hardness of the sheet member and a hardness of the film with respect to temperature; and
determining the cooling temperature based on measured results.

9. The semiconductor chip manufacturing method according to claim 8, wherein
the cooling the sheet member and the film to the cooling temperature includes cooling the sheet member and the film to the cooling temperature determined in a cooling temperature range in which the film is harder than the sheet member and a hardness of the sheet member is smaller than a predetermined value.

10. The semiconductor chip manufacturing method according to claim 9, wherein
the cooling the sheet member and the film to the cooling temperature includes cooling the sheet member and the film to the cooling temperature determined to be a temperature on a higher side in the cooling temperature range when the sheet member has a larger variation in the hardness with respect to temperature than the film.

11. The semiconductor chip manufacturing method according to claim 9, wherein
the cooling the sheet member and the film to the cooling temperature includes cooling the sheet member and the film to the cooling temperature includes cooling the sheet member and the film to the cooling temperature determined to be a temperature on a lower side in the cooling temperature range when the sheet member has a smaller variation in the hardness with respect to temperature than the film.

12. A semiconductor chip manufactured by an expanding device, the expanding device comprising:
a cooler configured to cool an extensible sheet member on which a wafer including a plurality of semiconductor chips is arranged and a film on the wafer to a cooling temperature at which the film becomes harder than the sheet member; and
an expander configured to expand the sheet member cooled to the cooling temperature by the cooler to divide the wafer into the plurality of semiconductor chips.

13. The expanding device according to claim 2, wherein
the cooler is configured to cool the sheet member and the film to the cooling temperature in a cooling temperature range in which the film is harder than the sheet member and a hardness of the sheet member is smaller than a predetermined value.

14. The semiconductor chip manufacturing method according to claim 7, further comprising:
measuring a hardness of the sheet member and a hardness of the film with respect to temperature; and
determining the cooling temperature based on measured results.
